(19) United States
(12) Patent Application Publication
(10) Pub. No.: US 2016/0071702 A1
(43) Pub. Date: Mar. 10, 2016

(54) ARC-PLASMA FILM FORMATION DEVICE

(71) Applicant: Shimadzu Corporation, Kyoto-shi (JP)

(72) Inventors: Masayasu SUZUKI, Kyoto-shi (JP); Yosuke MORIMOTO, Kyoto-shi (JP)

(21) Appl. No.: 14/773,573

(22) PCT Filed: Oct. 29, 2013
(86) PCT No.: PCT/JP2013/079261

§ 371 Date: Nov. 11, 2015

(30) Foreign Application Priority Data
Mar. 8, 2013 (JP) PCT/JP2013/056420

(51) Int. Cl. H01J 37/32

(52) U.S. Cl. CPC H01J 37/32669; H01J 37/32055; H01J 37/32357; H01J 37/32899; H01J 37/32568; H01J 37/32596; H01J 2237/002; H01J 2237/006; H01J 2237/06375; H01J 2237/152; H01J 2237/162; H01J 2237/327; H01J 2237/3326

(57) ABSTRACT

An arc-plasma film formation device includes a film formation chamber in which a substrate to be treated is stored, a plasma chamber in which at least a part of a target is stored, the plasma chamber being configured to be connected to the film formation chamber, and a plurality of hollow coils configured to generate a continuous line of magnetic force between the target and the film formation chamber and having at least one curved section, the plurality of hollow coils being arrange in the plasma chamber and covered by an outer coat made of a non-magnetic metal. Plasma containing ions derived from the target material and generated in the plasma chamber as a result of arc discharge is transported from the target to the substrate by passing an inside of the plurality of hollow coils.

### TECHNICAL FIELD

The present invention relates to an arc-plasma film formation device configured to perform film formation processing using arc-plasma.

### BACKGROUND TECHNIQUE

For forming a thin film, etc., an arc-plasma film formation device using arc-plasma is used. An arc-plasma film formation device forms arc-plasma containing ions of a material element contained in a target as a result of arc discharge to thereby form a thin film containing the material element as a main ingredient on a substrate to be treated.

In an arc-plasma film formation device, by controlling a magnetic field formed by a plurality of coils arranged outside a curved chamber having a curved section, arc-plasma formed on a target is induced to a surface of a substrate with the curved chamber functioning as a plasma transportation part. To prevent adhesion of electrically neutral droplets (rough particles) emitted and scattered from the target to the substrate, a curved chamber is used. With this, the incident of the droplets linearly emitted from the target surface to the film formation surface of the substrate can be restrained.

The coil is arranged outside the curved chamber, and therefore the coil is large. For this reason, to obtain a predetermined magnetic field, it is required to increase the current to the coil or to increase the number of turns of the coil. For example, in the case of using a hollow coil as a magnetic field generation mechanism, the hollow coil to be arranged at the curved section will be inevitably increased in the structural size.

Further, if only the plasma transport part is arranged in a vacuum chamber and the hollow coil is arranged on an atmospheric pressure side which is outside the plasma transport part, the hollow coil will be increased in size and the freedom of the installation position of the hollow coil will be limited. If there is no degree of freedom in the installation position of the hollow coil, the control range of the curved trajectory and/or the curvature will become extremely narrow, resulting in difficulty in effective plasma transportation. Especially, the hollow coil to be arranged at the curved section is required to be produced so as to be wound on the corner part of the curved chamber, which requires a manual winding work because of the structure. Thus, it is difficult to ensure the homogeneity of construction and shape, and therefore variations in the strength of generated magnetic field and the strength distribution, which is a coil performance, inevitably occur for each machine, which makes it difficult to ensure the production reliability.

For this reason, a method is proposed in which a plasma transportation path and a magnetic field generation part are both arranged in a vacuum chamber (see Patent Document 1 and Patent Document 2).

### PRIOR ART

### Patent Documents

Patent Document 1: Japanese Unexamined Patent Application Publication No. 2012-12641

Patent Document 2: U.S. Pat. No. 6,548,817

### SUMMARY OF THE INVENTION

### Problems to be Solved by the Invention

However, in the invention described in Patent Document 1, a double tube is arranged to flow cooling water through the coil. However, the coil cooling efficiency is low only by this structure. Therefore, it is difficult to increase the magnetic field strength by increasing the amount of current, resulting in inefficient plasma transportation. In order to improve the cooling efficiency, it is required to extend the cooling path. However, this increases the cross-sectional area of the coil, resulting in an increased device size. As a result, the freedom of the installation position of the hollow coil cannot be secured, which makes it difficult to attain efficient plasma transportation. Especially, the adjustment of magnetic flux at the curved section is difficult, and the effective transportation of the plasma is difficult. Thus, there is a concern that the film forming rate is reduced and the particle generation is promoted. Further, in the invention described in Patent Document 1, although the magnetic field generation part is arranged in a vacuum chamber, the hollow coil is arranged on the atmospheric pressure side. This is because if the hollow coil is arranged in the vacuum chamber, plasma is directly irradiated on the hollow coil to cause frequent deterioration and/or breakage of the hollow coil.

On the other hand, in the invention described in Patent Document 2, a torus type coil is used, and therefore there is a concern that a damage of the inside portion of the hollow coil used for plasma transportation due to the discharge or heat generation at the power feeding portion. This is due to the following reasons. That is, a magnetic field strength to be generated by a coil is basically determined by a current value×the number of turns. In the torus type coil, it is difficult to secure a large number of turns in a certain range (certain range in the transportation direction), and therefore it is required to increase the current value to obtain a predetermined magnetic field strength. This in turn causes a concern of abnormal discharge and/or heat generation at the coil power feeding portion by a large current.

In view of the aforementioned problems, the present invention aims to provide an arc-plasma film formation device capable of controlling incident of droplets to a film formation surface of a substrate and attaining effective plasma transportation.

### Means for Solving the Problems

According to one embodiment of the present invention, an arc-plasma film formation device is provided with (a) a film formation chamber in which a substrate of a processing target is stored, (b) a plasma chamber in which at least a part of a target is stored, the plasma chamber being connected to a film formation chamber, (c) a plurality of hollow coils configured to generate a continuous line of magnetic force having at least one curved portion between the target and the film formation chamber, the plurality of hollow coils being covered by an outer coat made of a non-magnetic metal and arranged in the plasma chamber, and (d) a plasma potential correction tube arranged inside the hollow coil, wherein plasm containing ions derived from a target material and generated in the plasma chamber as a result of arc discharge passes through an inside of the plurality of hollow coils to be transported to a substrate from the target.

### Effects of the Invention

According to the present invention, the arc-plasma film formation device capable of controlling incident of droplets to a film formation surface of a substrate and attaining effective plasma transportation can be provided.

### BRIEF DESCRIPTION OF THE DRAWINGS

FIG. 1 is a schematic view showing a structure of an arc-plasma film formation device according to a first embodiment of the present invention.

FIG. 2 is a schematic cross-sectional view showing a structure of a plasma chamber of the arc-plasma film formation device according to the first embodiment of the present invention.

FIG. 3 is a schematic view for explaining plasma transportation.

FIG. 4 is a schematic view for explaining magnetic fields formed by hollow coils of the arc-plasma film formation device according to the first embodiment of the present invention.

FIG. 5 is a schematic view showing a structure of the hollow coil of the arc-plasma film formation device according to the first embodiment of the present invention.

FIG. 6 is a schematic view showing another structure of the hollow coil of the arc-plasma film formation device according to the first embodiment of the present invention.

FIG. 7 is a schematic view showing an adjustment direction of an arrangement of the hollow coils of the arc-plasma film formation device according to the first embodiment of the present invention.

FIG. 8 is a schematic view showing an example of a plasma transportation path of the arc-plasma film formation device according to the first embodiment of the present invention.

FIG. 9 is a schematic view showing a relation of an arrangement of the hollow coils and a two-dimensional curved transportation path of plasma in the arc-plasma film formation device according to the first embodiment of the present invention, wherein FIG. 9A is a side view thereof and FIG. 9B is a plan view thereof.

FIG. 10 is a schematic view showing a relation of another arrangement of the hollow coils and a two-dimensional curved transportation path of plasma in the arc-plasma film formation device according to the first embodiment of the present invention, wherein FIG. 10A is a side view thereof and FIG. 10B is a plan view thereof.

FIG. 11 is a schematic cross-sectional view showing a structure of the hollow coil of the arc-plasma film formation device according to the first embodiment of the present invention.

FIG. 12 is a schematic view showing a structure of an arc-plasma film formation device according to a second embodiment of the present invention.

### EMBODIMENTS FOR CARRYING OUT THE INVENTION

Embodiments of the present invention will be explained with reference to attached drawings. In the descriptions of the following drawings, the same or similar symbols are allotted to the same or similar portions. However, it should be noted that the drawings are schematic. Further, the following embodiments exemplify a device and a method for embodying the technical concept of the present invention, and the embodiments of the present invention are not intended to be limited to the following structure and/or the arrangement of the structural parts. In the embodiments of the present invention, various modifications can be made within the scope of claims.

### First Embodiment

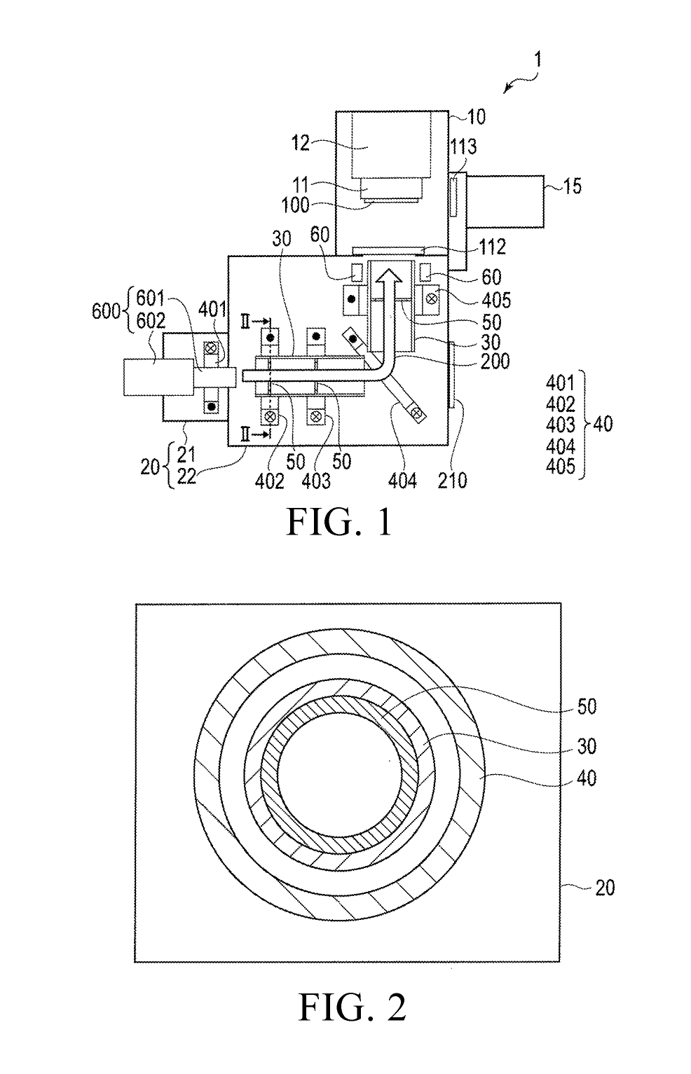

The arc-plasma film formation device 1 shown in FIG. 1 according to the first embodiment of the present invention is a film formation device for generating plasma 200 including ions of a material element contained in a target 600 as a result of arc discharge generated with the target 600 functioning as a negative pole (cathode). According to the arc-plasma film formation device 1, a thin film containing the material element of the target 600 as a main component is formed on a substrate 100 to be treated.

The arc-plasma film formation device 1 includes, as shown in FIG. 1, a film formation chamber 10 in which a substrate 100 to be treated is stored, a plasma chamber 20 in which at least a part of a target 600 is stored, the plasma chamber being connected to the film formation chamber 10, and first to fifth hollow coils 401 to 405 arranged in the plasma chamber 20 to generate a continuous line of magnetic force having at least one curved section between the target 600 and the film formation chamber 10. Hereinafter, the first to fifth hollow coils 401 to 405 will be collectively referred to as “hollow coil 40.” The plasma 200 containing ions deriving from the material of the target 600 and generated in the plasma chamber 20 as a result of arc discharge passes through the inner side of the hollow coils 40 to be transported from the target 600 to the substrate 100.

Further, for the purpose of preventing the plasma 200 from being diffused or leaked between the hollow coils 40, a plasma potential correction electrode may be arranged around a space between the hollow coils 40. The plasma 200 is transported by passing inside the plasma potential correction electrode. In the example shown in FIG. 1, plasma potential correction tubes 30 are arranged inside the first hollow coil 401 to the fifth hollow coil 405. The plasma 200 is transported by passing through the inside of the plasma potential correction tubes 30.

In the embodiment shown in FIG. 1, the plasma chamber 20 includes a target chamber 21 and a discharge chamber 22. In the target chamber 21, a target 600 and a first hollow coil 401 are stored, and a part of the target 600 is arranged so as to be exposed in the discharge chamber 22. In the discharge chamber 22, plasma 200 as a result of arc discharge is generated. For example, an end portion of the circular cylindrical target 600 is exposed to the inside of the discharge chamber 22, and arc discharge plasma is formed on the surface of the exposed target 600.

The target 600 includes a target material 601 which is a material for forming a film on a substrate 100 and a target case 602 in which the target material 601 is stored. For example, in the case of forming a carbon film such as a diamond-like carbon (DLC) film on the principal surface of the substrate 100, a carbon target is used as the target 600. The target chamber 21 and the discharge chamber 22 are detachable. In a state in which the target chamber 21 is detached from the discharge chamber 22, the replacement, etc., of the target 600 to be stored in the target chamber 21 can be performed easily.

The cross-sectional view taken along in the II-II direction in FIG. 1 is shown in FIG. 2. As shown in FIG. 1 and FIG. 2, a throttle plate 50 having an opening at its central portion through which plasma 200 passes is arranged inside the plasma potential correction tube 30. The throttle plate 50 is arranged in a region surrounded by the hollow coil 40. The detail of the throttle plate 50 will be explained later.

The hollow coil 40 forms a magnetic field so that the plasma 200 generated on the surface of the target 600 by the arc discharge energized in the plasma chamber 20 passes through the inside of the plasma potential correction tube 30 and is guided from the plasma chamber 20 to the primary surface of the substrate.

The hollow coil 40 is, for example, an electromagnetic induction coil excited by a supplied current, and a plasma potential correction tube 30 is arranged with the center thereof aligned with the center of the hollow coil. Depending on the magnitude of the current supplied from an excitation current source not illustrated, the intensity and the direction of the magnetic field formed by the hollow coil 40 are controlled, respectively. By controlling the current flowing through the hollow coil 40, the central magnetic field is controlled, so that the plasma 200 is guided so as to pass through the inside of the hollow coil 40.

FIG. 1 illustrates an embodiment in which the number of hollow coils 40 arranged in the plasma chamber 20 is 5. However, the number of hollow coils 40 is not limited to five, and can be arbitrarily set depending on the shape and/or the length of the plasma transportation path.

The first hollow coil 401 arranged in the target chamber 21 is arranged, as shown in FIG. 1, at a position deviated away from the surface of the target 600 where the plasma 200 is formed in the thickness direction of the target 600. That is, the first hollow coil 401 is arranged so as to face the second hollow coil 402 which is most closely arranged to the target 500 among the plurality of hollow coils 40 arranged in the discharge chamber 22 across the plane level including the surface of the target 600.

By the first hollow coil 401 and the second hollow coil 402 arranged near the target 600, a magnetic field on the surface of the target 600 is formed. The first hollow coil 401 and the second hollow coil 402 are set so as to form a cusp magnetic field. That is, the first hollow coil 401 and the second hollow coil 402 form magnetic fields opposite in direction, resulting in a stable generation of long-life arc discharge, which in turn can improve the efficient of a film formation treatment by arc plasma.

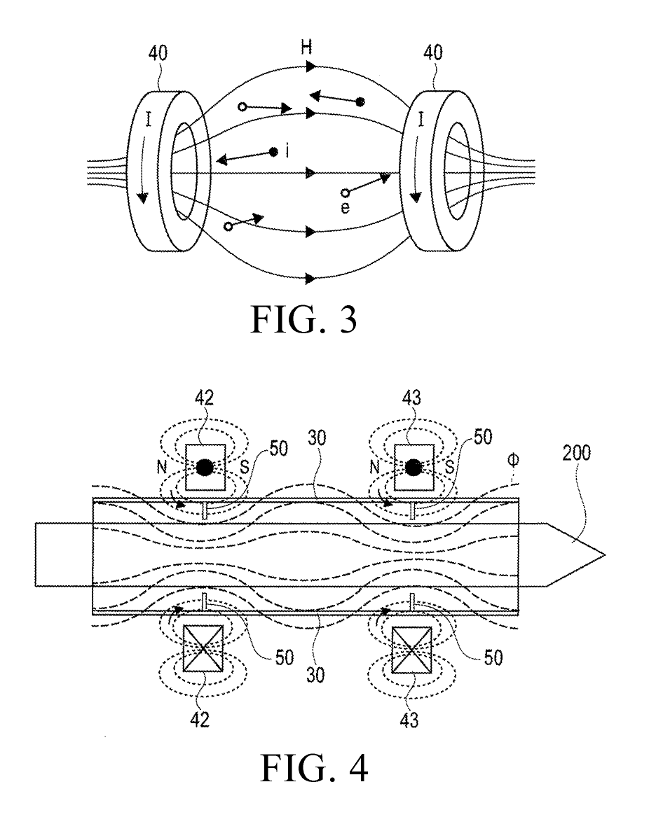

On the other hand, the second hollow coil 402 and the fifth hollow coil 405 are set so as to firm a mirror magnetic field. As shown in FIG. 3, the electron e is transported in the direction of the magnetic field H (from the N pole to the S pole) generated by the current I flowing through the hollow coil 40 while EB drifting so as to wind around the line of magnetic force. The ion i is less influenced by the magnetic field, and therefore is transported as plasma integrally with the electron while being pulled back in the motion direction of the electron by the bipolar diffusion. In other words, plasma itself is transported such that the electron is transported by the magnetic field and the ion follows the movement of the electron. The plasma to be transported becomes a shape expanded or narrowed along the line of magnetic force.

As explained above, by the magnetic fields formed by the second hollow coil 402 to the fifth hollow coil 405, the plasma 200 containing ions of the material element is transported to the film formation chamber 10. On the other hand, by the scan coil 60, the magnetic field above the substrate 100 is scanned. With this, an even film is formed on the principal surface of the substrate 100.

FIG. 4 shows the status of magnetic fields in the surroundings of the second hollow coil 402 and the third hollow coil 403. As shown in FIG. 4, a current is applied to the hollow coil 40 so that magnetics field in which the target 600 side is an N pole are generated. The second hollow coil 402 and the third hollow coil 403 form mirror magnetic fields, and the plasma 200 is transported in the direction from the second hollow coil 402 toward the third hollow coil 403.

By controlling respective positions of the plurality of hollow coils 40 arranged in the discharge chamber 22, strengths and/or directions of magnetic fields generated, directions of the lines of magnetic forces formed by the hollow coils 40 can be set. With this, the plasma 200 is curved and transported through an intended path so as to penetrate through the inner side of the hollow coil 40.

For example, as shown in FIG. 1, an L-shaped plasma transportation path having one curved section can be formed between the film formation chamber 10 and the plasma chamber 20. Alternatively, a plasma transportation path having a plurality of curved sections like a U-shaped path may be formed. By forming a curved section(s) in the plasma transportation path or extending the plasma transportation path, it becomes possible to control reaching of droplets or particles to the substrate 100.

As mentioned above, according to the arc-plasma film formation device 1, regardless of the shape of the plasma chamber 20, a plasma transportation path having a plurality of curvatures and/or a minute curvature(s) can be realized. That is, by adjusting the number and/or positions of the hollow coils 40 to be arranged inside the plasma chamber 20 without changing the shape of the plasma chamber 20, it becomes possible to attain complex plasma curved transportation. For this reason, an effective plasma transportation can be attained, and droplet suppression effects can be obtained.

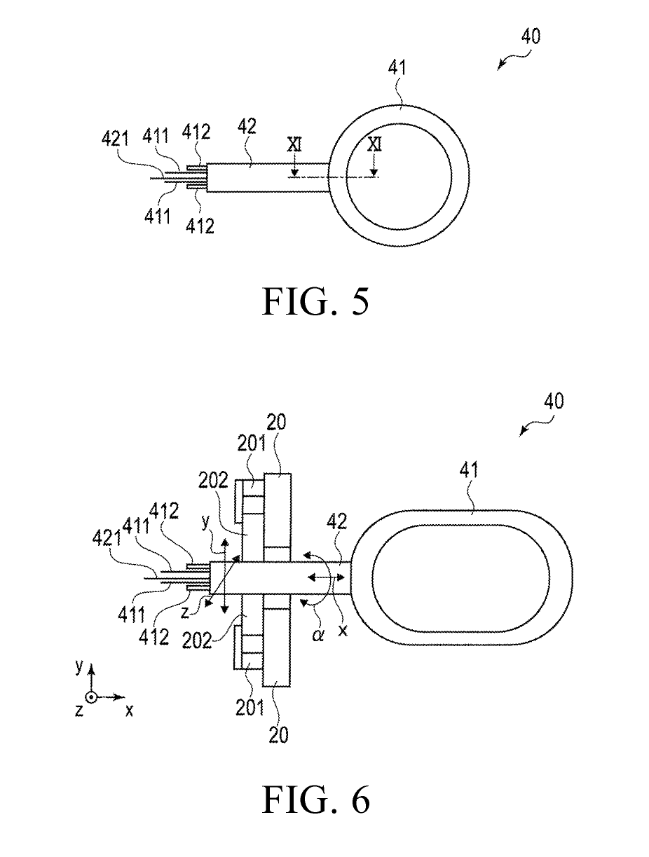

As for the shape of the hollow section of the hollow coil 40, a circular shape, an elliptical shape, etc., can be employed. For example, the shape of the hollow section of the first hollow coil 401, the second hollow coil 402, the third hollow coil 403 and the fifth hollow coil 405 to be arranged in a region in which the plasma transportation path is linear is set to a circular shape as shown in FIG. 5. On the other hand, the shape of the hollow section of the fourth hollow coil 404 to be arranged in a region in which the plasma transportation path is curved is set to an elliptical shape as shown in FIG. 6.

As shown in FIG. 5 and FIG. 6, the hollow coil 40 includes an annular portion 41 and a handle portion 42. The plasma 200 is transported inside the annular portion 41 constituting the hollow section. With the handle portion 42, the hollow coil 40 is supported by the plasma chamber 20. The mounting portion of the hollow coil 40 of the plasma chamber 20 is, as shown in FIG. 6, constituted by a fixed portion 201 fixed to the plasma chamber 20 and a movable portion 202 connected to the handle portion 42. By sliding the movable portion 202 supported by the fixed portion 201, the arrangement of the hollow coil 40 in the plasma chamber 20 can be adjusted in a state in which the hollow coil 40 is attached to the plasma chamber 20. With this, the magnetic field layout in the plasma chamber 20 can be changed easily.

For example, as shown by arrows in FIG. 6, the hollow coil 40 can be moved in the right-left direction (x-direction) or the up-down direction (y-direction) perpendicular to the plasma transportation path, or in the front-back direction (z-direction) along the plasma transportation path. Further, the hollow coil 40 can be rotated in the a-direction about the extending direction of the handle portion 42 as a rotation axis. Although not illustrated, the first hollow coil 40, the second hollow coil 402, the third hollow coil 403, and the fifth hollow coil 405 are also attached to the plasma chamber 20 in the same manner as in the fourth hollow coil 404. The adjustment range of the arrangement of the hollow coil 40 is set to, for example, about ±10 cm in the front-back direction and ±15 degrees in the rotation direction.

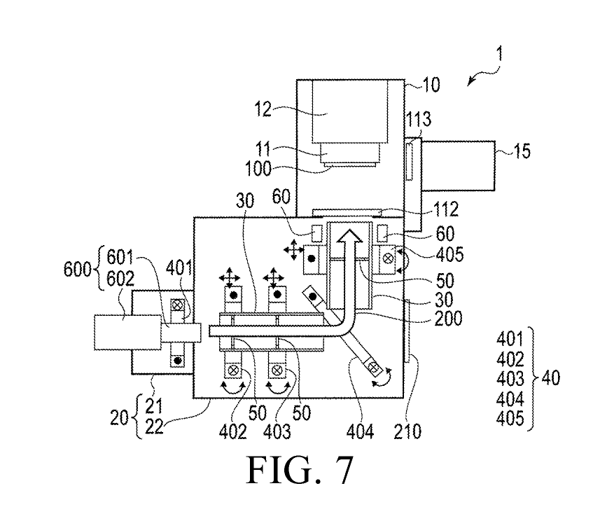

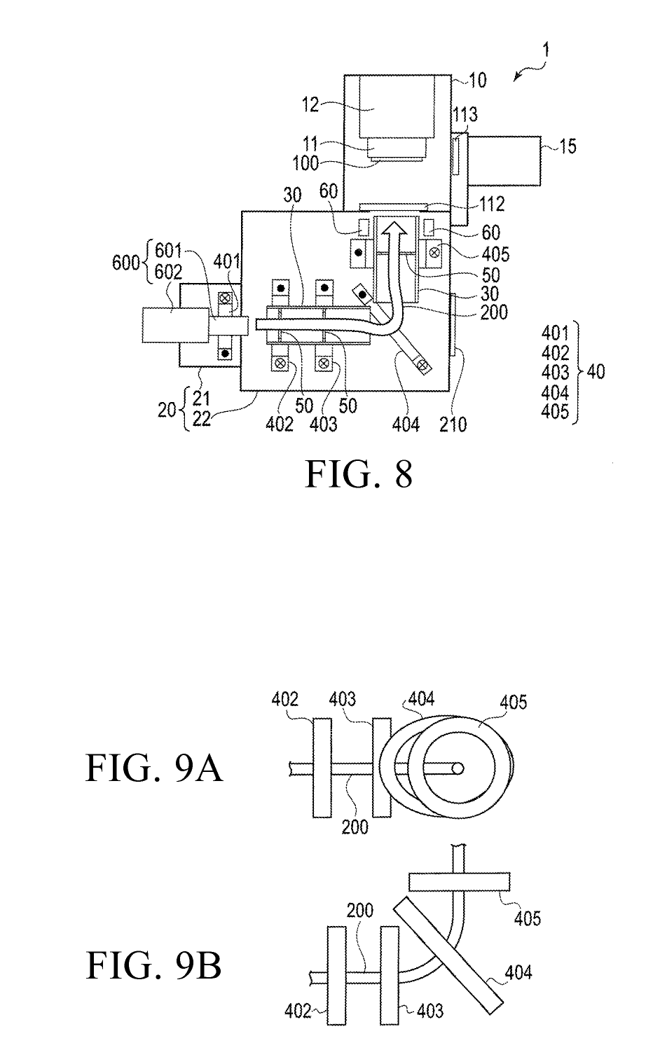

As shown by the arrows in FIG. 7, by adjusting the arrangement of the hollow coil 40, the plasma transportation path can be adjusted freely. For this reason, according to the arc-plasma film formation device 1, the efficiency of the plasma transportation can be improved. Further, as shown in FIG. 8, the plasma transportation path can be largely diverted at the periphery of the fourth hollow coil 404. As a result, reaching of droplets and/or particles to the substrate 100 can be controlled more effectively.

Concretely, in the case of realizing a plasma transportation path having a curved portion with no diversion as shown in FIG. 9A and FIG. 9B, the hollow coils 40 are arranged so that central axes passing centers of the magnetic fields formed by the respective coils 40 continue on the same plane. At this time, each central axis linearly continues except for the curved section. On the other hand, in order to divert the plasma transportation path, the hollow coil 40 is moved in the up-down direction (y-direction in FIG. 6) or in the right-left direction (x-direction in FIG. 6) so as to displace the center position of the magnetic fields, or the hollow coil 40 is rotated.

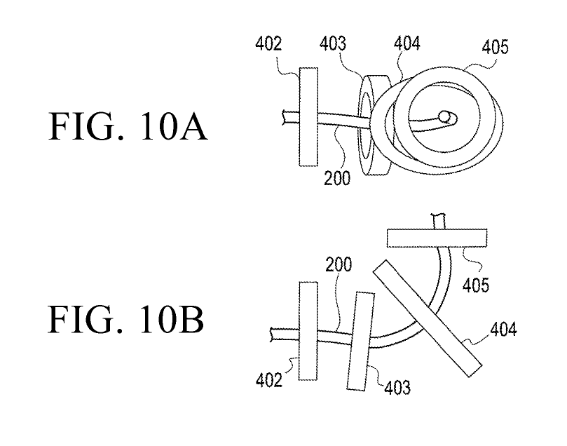

In the example shown in FIG. 10A and FIG. 10B in which the plasma transportation path is diverted, the third hollow coil 403 and the fourth hollow coil 404 are moved respectively, and the third hollow coil 403 is rotated. For example, the movement distance of the third hollow coil 403 is 5 mm in the traveling direction of the plasma 200 with respect to the front-back direction and 5 mm in the downward direction. Further, the third hollow coil 403 is rotated about a line passing the center of the magnetic field as a central axis, and the rotated angle is 3 degrees. Further, the movement distance of the fourth hollow coil 404 is 10 mm in the right direction, 5 mm in the traveling direction, and 5 mm in the downward direction.

As shown in FIG. 10A and FIG. 10B, by arranging a plurality of independent hollow coils 40, it becomes possible to set three dimensional stereoscopic plural successive curvatures, which is effective in reducing droplets and/or particles reaching the substrate 100. Further, the curvature of the plasma transportation path in the curved section can be increased, improving the disappearance rate of electrons, which in turn improves transportation efficiency. As explained above, in the arc-plasma film formation device 1, it is possible to perform an effective plasma transportation and also possible to perform a filtered cathodic vacuum arc method (FCVA) with less particles.

As shown in FIGS. 5 and 6, coil wires 411 for supplying electric current to the hollow coil 40, water-cooled tubes 412 for supplying cooling water, and a thermocouple 421 for measuring an inner temperature of the hollow coil 40 are introduced into the hollow coil 40 via the handle portion 42 from the outside of the plasma chamber 20.

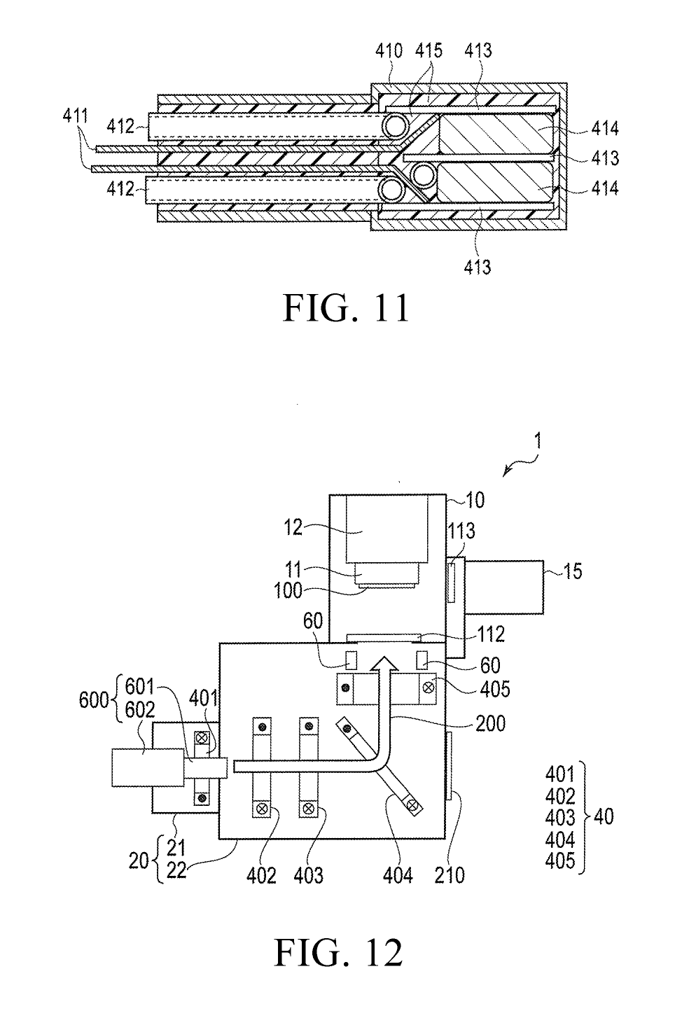

FIG. 11 shows a structure example of the hollow coil 40. FIG. 11 is a cross-sectional view taken along the line in the direction XI-XI in FIG. 5.

The hollow coil 40 is covered by an outer coat 410 made of a non-magnetic metal. In order to generate a magnetic field by the hollow coil 40, a magnetic metal cannot be used for the outer coat 410 since a magnetic metal blocks a magnetic field. Materials other than a magnetic metal can be used for the outer coat 410, and for example, a stainless steel alloy, an aluminum alloy, and a copper alloy can be used as a material for the outer coat 410. However, since it is arranged in vacuum, the outer coat 410 is required to have a predetermined strength. The outer coat 410 is set to the same electric potential as the plasma chamber 20.

As shown in FIG. 11, in the inner side of the hollow coil 40, coil wires 411, water-cooled tubes 412, water-cooled plates 413, and coil sections 414 are arranged. An electric current is supplied to the coil sections 414 arranged circularly along the annular portion 41 of the hollow coil 40 via the coil wires 411, so that the hollow coil 40 generates a magnetic field.

Further, the inside of the hollow coil 40 is vacuum-deaerationally filled with a resin 415 having a thermal conductivity. As the resin 415, for example, an epoxy resin, etc., can be used. The thermal conductivity of the resin 415 is preferably as higher as possible.

In the water-cooled tubes 412, for example, cooling water is flowed, and the water-cooled plate 413 is cooled by the water-cooled tubes 412. As the materials for the water-cooled tube 412 and the water-cooled plate 413, for example, copper, etc., can be used. By the water-cooled plate 413, the coil section 414 sandwiched by the water-cooled plates 413, the resin 415 and the outer coat 410 are cooled. With this, the temperature increase of the hollow coil 40 can be controlled effectively. For this reason, the magnetic field strength can be easily increased by increasing the current amount of the hollow coil 40.

In the arc-plasma film formation device 1, by arranging the hollow coil 40 in the plasma chamber 20, the coil used for the plasma transportation can be reduced in size. In the case of a hollow coil 40 small in shape, even if the current amount is small, an effective plasma transportation can be performed. Further, by effectively cooling the hollow coil 40 as explained above, a strong coil magnetic field can be realized with good reproducibility.

In the example shown in FIGS. 1 and 2, the plasma potential correction tube 30 is arranged in the hollow portion of the hollow coil 40. Since possible divergent or leakage of the plasma 200 from between the hollow coils 40 can be prevented by the plasma potential correction tube 30, more effective plasma transportation can be performed. Further, to decrease the plasma diameter of the plasma 200 to be transported, the plasma potential correction tube 30 is effective. By decreasing the plasma diameter, the device can be reduced in size.

As the material for the plasma potential correction tube 30, to avoid blocking of the magnetic field generated by the hollow coil 40, a magnetic material cannot be used. For example, a non-magnetic metal material, such as, e.g., a stainless steel alloy, an aluminum alloy, and a copper alloy, can be used for the plasma potential correction tube 30.

In FIG. 1, an example in which the plasma potential correction tube 30 is a straight tube is exemplified, but a curved tube can be used for the plasma potential correction tube 30. However, in the region facing the target 600, it is preferable that the plasma potential correction tube 30 is not arranged. That is, the surface facing the target 600 is a portion high in droplet irradiation frequency. Therefore, by forming this portion of the plasma potential correction tube 30 into an open shape, it becomes possible to control the scattering and/or diffusion of droplets by collision to the plasma potential correction tube 30. For this reason, the particle adhesion rate to the substrate 100 can be reduced.

The plasma potential correction tube 30 is insulated from the surrounding structure. The electrical potential of the plasma potential correction tube is preferably set to a range of −20 V to +20 V for an experimental plasma effective transportation.

As already explained, in the plasma potential correction tube, a throttle plate 50 for collecting droplets is arranged. Droplets of high kinetic energy are collected by the throttle plate 50, which can reduce the particle adhesion rate at the substrate 100. As the material for the throttle plate 50, in the same manner as in the plasma potential correction tube 30, a non-magnetic metal material, such as, e.g., a stainless steel alloy, an aluminum alloy, and a copper alloy, can be used. The electrical potential of the throttle plate 50 is the same potential as the plasma potential correction tube 30.

As shown in FIG. 4, the magnetic flux lines Φ is narrowed just below the hollow coil 40, the plasma 200 is narrowed. On the other hand, at the midpoint between the hollow coils 40, the magnetic flux lines Φ is expanded. Therefore, when the throttle plate 50 is arranged at the midpoint between the hollow coils 40, the plasma 200 will disappear. However, by arranging the throttle plate 50 just below the hollow coil 40, even if the diameter of the plasma potential correction tube 30 is essentially narrowed by the throttle plate 50, the efficiency of the plasma transportation will not be decreased.

Further, as shown in FIG. 1, in the plasma chamber 20, an easily openable and closable take-out window 210 is provided. Through the take-out window 210, the plasma potential correction tube 30 can be taken out to the outside from the inside of the plasma chamber 20. For this reason, the maintenance of the plasma potential correction tube 30 can be performed easily. The take-out window 210 is arranged, for example, at the surface facing the target 600. According to the structure in which the entire plasma chamber 20 is opened by the take-out window 210, the maintenance can be performed easily.

At the connection portion of the plasma chamber 20 and the film formation chamber 10, a gate valve 112 is provided. At the time of the film forming processing, the gate valve 112 is opened. By closing the gate valve 112, for example, while keeping one of the plasma chamber 20 and the film formation chamber 10 in a vacuum state, the other thereof can be opened to the atmosphere. With this, the maintenance can be performed easily.

Further, to the film formation chamber 10, a take-in chamber 15 is connected via the gate valve 113. Through the take-in chamber 15, the substrate 100 is stored in the film formation chamber 10. Taking out the substrate 100 can also be performed via the take-in chamber 15. In a state in which the substrate 100 is mounted on a work adaptor 11, the storing into and taking out from the film formation chamber 10 is performed. In the film formation chamber 10, the work adaptor 11 to which the substrate is mounted is arranged on the holder 12.

Although not illustrated, the film formation chamber 10, the plasma chamber 20 and the take-in chamber 15 are equipped with an exhaust system, respectively. For this reason, exhaust ventilation can be performed individually.

As already mentioned, droplets are generated from the target 600 as a result of arc discharge. The droplets are not charged particles, and therefore travel linearly without being affected by the magnetic field. Therefore, by proving a curved section in the plasma transportation path, it becomes possible to prevent the droplets from reaching the substrate 100.

However, in the case of using a curved chamber, droplets repeat collision against the chamber inner wall and diffusion to be scattered, which increases the possibility of adhesion to the surface of the substrate 100. Thus, a good quality thin film cannot be formed.

Further, the inner side of the curved chamber is narrow and occlusive, and therefore it is difficult to remove droplets, deposits, or precipitates of particles inside the chamber. Adhesion of these deposits or precipitates to the surface of the substrate 100 causes deterioration of quality of the thin film to be formed on the substrate 100.

On the other hand, in the arc-plasma film formation device 1 according to the first embodiment, by adjusting the number or position of the hollow coils to be arrange inside the plasma chamber 20, a complex plasma curved transportation can be performed. Further, without being restricted by the curved chamber, the degree of freedom of the installation position of the hollow coils 40 is high, which enables more effective plasma transportation. Further, by using small hollow coils 10 capable of being effectively cooled, a strong coil magnetic field can be formed.

Further, in the arc-plasma film formation device 1, the plasma potential correction tube 30 can be taken out to the outside form the take-out window 210. For this reason, deposits or precipitate in the plasma potential correction tube 30 can be removed easily. As a result, a high quality thin film can be formed on the substrate 100.

Thus, according to the arc-plasma film formation device 1, incident of droplets is controlled, and the arc-plasma firm forming capable of performing effective plasma transportation enables to provide a film formation device causing less incorporation of particles to the film formation surface of the substrate 100.

In FIG. 1, an example in which the plasma potential correction electrode arranged around the space between the hollow coils 40 is the plasma potential correction tube 30 is exemplified. However, the plasma potential correction electrode is not limited to a tube shape, and can be, for example, a plate-shaped electrode can be arranged around the space between the hollow coils 40. By arranging so as to face plate-shaped electrodes across the plasma 200, the plasma 200 can be prevented from diverging or leaking from between the hollow coils 40.

### Second Embodiment

In the above embodiment, an example in which the arc-plasma film formation device 1 is equipped with plasma potential correction electrodes arranged around the space between the hollow coils 40 is shown. However, in cases where there is no need to consider diversion or leakage of the plasma 200 from between the hollow coils 40 since the plasma 200 flows stably, it is not required to arrange any plasma potential correction electrodes as shown in FIG. 12. By not arranging a plasma potential correction electrode such as a plasma potential correction tube 30 in the plasma chamber 20, the miniaturization or cost reduction of the device can be attained.

As explained above, the present invention was explained by embodiments, but it should not be understood that the description and drawings forming a part of this disclosure limit the present invention. From this disclosure, various alternative embodiments, examples and operation techniques will become apparent to one skilled in the art. That is, the present invention, of course, includes various embodiments not described here. Therefore, the technical scope of the present invention is determined only from the invention specifying items according to claims which are appropriate from the above explanation.

### INDUSTRIAL APPLICABILITY

The present invention is applicable to a film formation device which transports plasma containing ions of a material element by a magnetic field generated by a coil.

1. An arc-plasma film formation device comprising:
a film formation chamber in which a substrate to be treated is stored;
a plasma chamber in which at least a part of a target is stored, the plasma chamber being configured to be connected to the film formation chamber; and
a plurality of hollow coils configured to generate a continuous line of magnetic force having at least one curved section between the target and the film formation chamber, the plurality of hollow coils being arranged in the plasma chamber and covered by an outer coat made of a non-magnetic metal,
wherein plasma containing ions derived from the target material and generated inside the plasma chamber as a result of arc discharge is transported from the target to the substrate by passing through an inside of the plurality of hollow coils.

2. The arc-plasma film formation device as recited in claim 1,
wherein a coil section to which a current is supplied, a water-cooled tube through which cooling water flows, and a water-cooled plate to be cooled by the water-cooled tube are arrange inside the hollow coils, and
wherein an inside of the hollow coils is filled with a resin having a thermal conductivity.

3. The arc-plasma film formation device as recited in claim 1,
wherein a material of the outer coat of the hollow coil is any one of a stainless steel alloy, an aluminum alloy and a copper alloy.

4. The arc-plasma film formation device as recited in claim 1, further comprising a plasma potential correction electrode arranged around a space between the hollow coils,
wherein the plasma passes through an inside of the plasma potential correction electrode to be transported from the target to the substrate.

5. The arc-plasma film formation device as recited in claim 4,
wherein the material of the plasma potential correction electrode is any one of a stainless steel alloy, an aluminum alloy and a copper alloy.

6. The arc-plasma film formation device as recited in claim 4,
wherein the plasma potential correction electrode is not arranged in a region facing the target.

7. The arc-plasma film formation device as recited in claim 4,
wherein an electric potential of the plasma potential correction electrode is −20 V or higher but +20 V or lower.

8. The arc-plasma film formation device as recited in claim 4,
wherein the plasma potential correction electrode is a plasma potential correction tube arranged inside the hollow coil.

9. The arc-plasma film formation device as recited in claim 8,
wherein the plasma potential correction tube is a straight tube or a curbed tube.

10. The arc-plasma film formation device as recited in claim 8, further comprising a throttle plate arranged inside the plasma potential correction tube in a region in which a periphery of the throttle plate is surrounded by the hollow coil, the throttle plate being provided with an opening at a center portion through which the plasma passes.

11. The arc-plasma film formation device as recited in claim 10,
wherein the material of the throttle plate is any one of a stainless steel alloy, an aluminum alloy and a copper alloy.

12. The arc-plasma film formation device as recited in claim 4,
wherein the plasma chamber includes a take-out window for taking out the plasma potential correction electrode to an outside.

13. The arc-plasma film formation device as recited in claim 1,
wherein the hollow coils in the plasma chamber are individually adjustable in arrangement.

14. The arc-plasma film formation device as recited in claim 1,
wherein the hollow coils arranged between the target and the film formation chamber are set so as to form a mirror magnetic field.
